(19) United States
(12) Patent Application Publication
(10) Pub. No.: US 2026/0215036 A1
(43) Pub. Date: Jul. 23, 2026

(54) MESA POROSIFICATION METHOD FACILITATING CONTACT CREATION

(71) Applicant: COMMISSARIAT A L'ENERGIE ATOMIQUE ET AUX ENERGIES ALTERNATIVES, Paris (FR)

(72) Inventors: François LEVY, Grenoble Cedex 09 (FR); Carole PERNEL, Grenoble Cedex 09 (FR); Bernard AVENTURIER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/139,693

(22) PCT Filed: Dec. 19, 2023
(86) PCT No.: PCT/FR2023/052046

§ 371 Date: Jun. 16, 2025

(30) Foreign Application Priority Data
Dec. 21, 2022 (FR) FR2214157

(51) Int. Cl. H10H 20/81; H10H 20/01

(52) U.S. Cl. CPC H10H 20/8215; H10H 20/01335

(57) ABSTRACT

A method for porosifying (Al,In,Ga)N/(Al,In,Ga)N mesas includes providing a structure having a base substrate covered with (Al,In,Ga)N/(Al,In,Ga)N mesas, the base substrate including a support layer, a first layer of undoped GaN, a second layer of doped GaN and the mesas having a third layer of strongly doped (Al,In,Ga)N, connecting the structure and a counter electrode to a generator, immersing the structure and the counter electrode in a solution, and applying a voltage or a current so as to partially porosify the third layer of GaN of the mesas. At least one zone of the layer of strongly doped GaN is not porosified, each non-porosified zone forming an electrical conduction channel between the main faces of the third layer of porosified GaN.

### TECHNICAL FIELD

The present invention relates to the general field of color microscreens. The invention relates to a method for porosifying (Al,In,Ga)N/(Al,In,Ga)N mesas. The invention also relates to a structure thus obtained comprising porosified (Al,In,Ga)N/(Al,In,Ga)N mesas. The invention has uses in many industrial fields, and in particular in the field of color microscreens containing micro-LEDs.

### PRIOR ART

Color microscreens comprise pixels formed by blue, green and red sub-pixels (RGB pixels). In the rest of the description, these sub-pixels will be designated more simply as pixels for the sake of conciseness.

Blue and green pixels can be manufactured from nitride materials and red pixels from phosphide materials. To combine these three types of pixels on the same substrate, the “pick and place” technique is generally used. However, in the case of microscreens with pixels smaller than 10 μm, this technique can no longer be used because of not only the alignment problems, but also the time necessary to carry out such a technique at this scale. For screens with a large number of pixels (high definition), this “pick and place” technique is problematic in terms of time. In addition the pixels must be taken from different wafers, which requires successive transfers. Mass transfer techniques can also be used.

Another solution involves carrying out the color conversion with quantum dots (QD) or nanophosphors pumped by blue μLEDs coming from a single wafer, either transferred, or in a monolithic matrix (preferred case for microscreens). However, controlling the deposition of these materials on pixels having small dimensions is difficult and their flow resistance is not sufficiently robust.

It is therefore crucial to be able to obtain the three RGB pixels natively with the same family of materials and the growth of which is carried out on the same substrate. For this, InGaN is the most promising material. This material can, indeed, theoretically cover the entire visible spectrum according to its indium concentration. Blue micro-LEDs containing InGaN already show high luminance, much greater than their organic counterparts. To emit at wavelengths in green, the quantum wells (QWs) of the LED must contain at least 25% indium and for emission in red, it is necessary to have at least 35% indium. Unfortunately, the quality of the InGaN material beyond 20% In is degraded because of the low miscibility of InN in GaN, but also because of the high compressive stress inherent in the growth of the InGaN active zone on GaN.

It is therefore essential to be able to reduce the overall stress in the structures containing GaN/InGaN.

Currently, one of the most promising solutions involves porosifying the layer of GaN, as described for example in the two articles by Pasayat et al. (Materials 2020, 13, 213; Appl. Phys. Lett. 116 111101 (2020)). The method described in these articles comprises the following steps:
providing a stack comprising a substrate made of sapphire covered by a layer of unintentionally doped GaN (UID GaN), a layer of n+Si-doped GaN (5e10¹⁸ at/cm³) and a layer of unintentionally doped InGaN or GaN,
partially etching the stack to form the GaN/InGaN or GaN/GaN mesas; the thickness of the doped layer is only partially etched so that the residual doped layer at the bottom of the mesa allows the polarization of the doped layer of all the mesas (“ring polarization” or wafer-edge polarization for example),
carrying out a step of electrochemical porosification in a solution of oxalic acid (0.3M), the layer of doped GaN acting as an anode and a platinum wire acting as a cathode.

The porosified layer of GaN thus obtained can allow to grow a nitride LED structure containing InGaN of better crystalline quality, via the relaxation of the porous mesas generated.

Other articles cite the use of porous GaN for optoelectronic devices, for example the article by Zhang et al. (“A resonant cavity blue-violet light-emitting diode with conductive nanoporous distributed Bragg reflector”, Phys. Status Solidi A 214, 1600866 (2017)) and the article by Zhou et al. (“Thermal transport of nanoporous gallium nitride for photonic applications”, Journal of Applied Physics 125, 155106 (2019)).

To produce a native color micro-screen containing all-InGaN red, green, blue (RGB) micro-LEDs with porous mesas, the method comprises, for example, the following steps:
providing a structure comprising a substrate covered with mesas (FIG. 1A):
   the substrate comprising a support layer 14, a buffer layer 15, an unintentionally doped GaN layer 11, a doped or strongly doped GaN layer 12,
   the mesas comprising a layer 23′ of porosified GaN and a layer 24 of UID GaN,
   the mesas being covered by a re-epitaxied LED comprising n-InGaN 30 and p-InGaN 31, and more particularly at least one layer 30 of n-InGaN, an active zone with quantum wells and an upper layer 31 of p-InGaN,
forming an electrode 21 on the structure obtained: the electrode 21 comes in contact with at least a part of the upper layer 30 of p-InGaN (if this electrode is also present on the sides of the LED, it can be insulated from the electrode 21 by a dielectric layer 22 which can cover the sides of the layers 30 and 31 and/or a part of the layer 31 for example); then transferring the assembly onto a final substrate 20 (FIG. 1B), comprising a via (not shown), for example by metal-metal bonding,
removing the growth substrate, then creating contact, for example cathode contact 50 on the n-GaN with a transparent conductive oxide (TCO) 45 without blocking metal (FIG. 1C); passivation layers 40 can cover the TCO 45.

However, since there is a reduction in the vertical electrical conduction through the porosified mesas, it can be difficult to inject current into the n-InGaN through the porous mesas. Likewise, the heat dissipation is poor. These two factors reduce the reliability of the device obtained.

In order to improve the integration, it is possible to create contact of the InGaN on the cathode after transfer.

There are two possible approaches to this.

In a first approach shown in FIGS. 2A to 2C, it is possible to completely remove the porous part of the mesas. After removal of the growth substrate, an etching is carried out up to the layer 30 of n-InGaN of the LED. It is then possible to create metal contact 50 on the cathode. An electrically insulating layer 40 protects the layer 30 of the LED. However, this first approach has several disadvantages: after removal of the support layer 14, it is difficult to control on the substrate (wafer) level the removal of all the layers (Al,Ga,In)N to stop in the layer 30 made of n-InGaN that it is desired to contact, without reaching the active layer of the LED. Indeed, the epitaxy and especially the method(s) for removing the layers used generate a non-uniformity linked to the large thickness of the stack to be removed and the tolerance for stopping in the layer 30 of n-InGaN is low because of its small thickness. In addition, the strong relief of the contact is compatible with difficulty with an electrode made of conductive transparent oxide. The contact 50 of the metal cathode is blocking, which reduces the extraction.

In a second approach shown in FIGS. 3A to 3C, it is possible to partially remove the porous layer 23′ from the mesas then locally etch the porous layer 23′ to make contact with the layer 30 of non-porous InGaN of the LED. This would allow to improve the optical extraction via the presence of residual porosity on the surface. For this, a local etching of the porosity must be carried out, with a stop in the layer 30 of fine n-InGaN. Problems of non-uniformity can result therefrom, like with the first approach. The contact of the metal cathode is still blocking, which reduces the extraction.

In these two methods for manufacturing micro-LED arrays, a variation in the thickness (TTV: total thickness variation) of the GaN is introduced, not only at the wafer scale but also from wafer to wafer. These variations in thickness come both from the variations in thickness of the epitaxy but especially from the thinning methods or the planarization methods used to remove the buffer layers of the epitaxy several microns thick, due to the non-uniformities of the methods used.

### DISCLOSURE OF THE INVENTION

One goal of the present invention is to propose a method for manufacturing micro-LEDs overcoming the disadvantages of the prior art, and in particular a method allowing to easily create a contact on the n-InGaN with the cathode while maintaining good extraction.

For this, the present invention proposes a method for manufacturing and porosifying (Al,In,Ga)N/(Al,In,Ga)Nmesas comprising the following steps:
a) providing a structure comprising a base substrate covered with (Al,In,Ga)N/(Al,In,Ga)N mesas,
   the base substrate comprising a support layer, optionally a buffer layer made of (Al,Ga)N, a first layer of non-doped GaN, a second layer of doped GaN,
   the (Al,In,Ga)N/(Al,In,Ga)N mesas comprising a third layer of (Al,In,Ga)N having a first main face and a second main face, the third layer of (Al,In,Ga)N being strongly doped or the third layer of (Al,In,Ga)N comprising a first strongly doped part having a first electrical conductivity and a second part formed by one or more zones, the second part having a second electrical conductivity at least ten times lower than the first electrical conductivity, wherein a part of the second layer of doped GaN can extend into the mesas,
b) electrically connecting the structure and a counter electrode to a voltage or current generator,
c) immersing the structure and the counter electrode in an electrolytic solution,
d) applying a voltage or a current between the structure and the counter electrode so as to partially porosify the third layer of strongly doped (Al,In,Ga)N of the mesas or so as to porosify the first strongly doped part of the third layer of (Al,In,Ga)N of the mesas, whereby a layer of (Al,In,Ga)N comprising a first porosified part and a second part formed by one or more non-porosified zones is obtained, each non-porosified zone going from the first main face to the second main face of the partially porosified layer of (Al,In,Ga)N to form an electrical conduction channel.

The invention fundamentally differs from the prior art by the presence of one or more non-porosified zones in the mesas. The non-porosified zones have a higher electrical conductivity than the porosified zones. These non-porosified zones thus form electrical conduction channels.

Advantageously, during step a), a fourth layer of undoped or weakly doped (Al,In,Ga)N covers the third layer of strongly doped (Al,In,Ga)N of the (Al,In,Ga)N/(Al,In,Ga)N mesas or, after step d), a fourth layer of undoped or weakly doped (Al,In,Ga)N is deposited on the third porosified layer of (Al,In,Ga)N.

Advantageously, the fourth layer of undoped or weakly doped (Al,In,Ga)N is a layer of GaN.

Advantageously, the structure further comprises an additional layer of strongly doped GaN disposed between the first layer of undoped GaN and the second layer of doped GaN.

According to a first advantageous embodiment, step d) is carried out by stopping the voltage or the current before the complete porosification of the third layer of (Al,In,Ga)N, whereby the non-porosified zone corresponds to the central part of the layer of porosified (Al,In,Ga)N (that is to say the porosified part surrounds the porosified part). This allows to preserve non-porosified zones in the core of the mesas by interrupting the electrochemical porosification before completion. Thus, by choosing the electrochemical porosification conditions, the anodization is partial: it stops before having porosified the core of the mesas. The conductivity of the non-porous core remains intact and forms a preferred conduction channel. The relaxation of the edges is naturally favored by the free surfaces.

According to a second advantageous embodiment, one or more zones, having a second conductivity, are formed in the third layer of strongly doped (Al,In,Ga)N, the second conductivity being at least ten times lower than the first conductivity, whereby during step d), the zone(s) are not porosified and form electrical conduction channels. The second conductivity is obtained, for example, by locally degrading the conductivity of the mesas by ion implantation. Ion implantation allows to “de-dope” zones (i.e. to decrease the electrical conductivity of the zones) which will not be porosified or will be slightly porosified during the anodization method, which is very selective for doping. The decrease in conductivity allows to preserve conduction channels. The zone(s) of second conductivity are not or are slightly porosified during step d).

Advantageously, after step d), the method comprises a step during which a heat treatment is carried out, whereby the second electrical conductivity is increased and zones having a third electrical conductivity are obtained. This healing annealing allows to at least partially recover the conductivity of the implanted zone. The third electrical conductivity is greater than the second electrical conductivity. It is less than or equal to the first electrical conductivity.

According to another embodiment, the zone(s) of the third layer of (Al,In,Ga)N form rings, each ring defining a core preferably having an electrical conductivity at least ten times greater than the second electrical conductivity, whereby during step d), the cores are not porosified and form electrical conduction channels.

The rings extend from the first main face to the second main face of the third layer of strongly doped (Al,In,Ga)N. This allows to create, in the center of the rings having a degraded conductivity, n++ channels in the mesas. The n++ GaN of the channels in the mesas thus remains intact without implantation or porosification since it is protected with the less doped or even undoped “shell”. The shell having lower conductivity is, for example, obtained by ion implantation, in particular by implantation of He. Thus, the de-doped zone is in the shape of a tube. This option allows to preserve the epitaxied original doping. The electrical conductivity at the center of the ring is, for example, identical to the first electrical conductivity. The thickness of the shell (i.e. the thickness of the “walls” of the tube) is preferably at least 250 nm. The thickness is defined by the limitations of the lithography and of the implantation.

The third layer of (Al,In,Ga)N of step a) can be obtained according to the following steps:
providing a layer of strongly doped (Al,In,Ga)N having a first electrical conductivity,
locally reducing the electrical conductivity of the layer of (Al,In,Ga)N, to form a layer of (Al,In,Ga)N comprising a first strongly doped part having a first electrical conductivity and a second part formed by one or more zones, having a second electrical conductivity at least ten times lower than the first electrical conductivity.

The second conductivity is obtained, for example, by locally degrading the conductivity of the mesas by ion implantation. The ion implantation allows to “de-dope” zones (i.e. to decrease the electrical conductivity of the zones) which will not be porosified or will be poorly porosified during the anodization method, which is very selective for doping. The decrease in conductivity allows, in particular, to preserve conduction channels. The zone(s) of second conductivity are not or are slightly porosified during step d).

According to another advantageous alternative embodiment, the third layer of (Al,In,Ga)N of step a) is obtained according to the following steps:
providing a layer of (Al,In,Ga)N having a second electrical conductivity,
locally increasing the electrical conductivity of the layer of (Al,In,Ga)N, to form a layer of (Al,In,Ga)N comprising a first strongly doped part having a first electrical conductivity and a second part formed by one or more zones, having a second electrical conductivity at least ten times lower than the first electrical conductivity.

The electrical conductivity of the layer of (Al,In,Ga)N can be increased, for example, by ion implantation of Si. Healing annealing can also be carried out.

Advantageously, the first stack comprises three groups of mesas, each group of mesas being intended to form a red, green or blue micro-LED, each group of mesas having a different porosification rate or percentage of porosified surface.

The invention also relates to a method for manufacturing micro-LEDs comprising the following successive steps:
i) implementing the method for manufacturing mesas as defined above,
ii) implementing the following steps e) to g):
   e) on the structure obtained in step i), carrying out an epitaxial regrowth to form re-epitaxied LEDs comprising n-InGaN layers and a layer of p-doped InGaN, then forming a contact electrode (the contact electrode being an “upper” electrode before transfer and this same electrode being “lower” after transfer), wherein a passivation layer can be positioned between the contact electrode (anode) and the layer of p-doped InGaN, the passivation layer locally covering the layer of p-doped InGaN, for example at the sides of the layer of p-doped InGaN,
   f) transferring the structure onto a substrate, for example by metal-metal bonding,
   g) removing the support layer, if applicable the buffer layer made of (Al,Ga)N, the first layer of undoped GaN and part or all of the second layer of doped GaN (it is possible to stop the etching in this layer so that the remaining part is part of the mesa),
   h) creating contact on the non-porosified zone or at least on one of the non-porosified zones of the porosified layer of (Al,In,Ga)N.

Such a method is particularly advantageous since it is possible to:
generate mesas with different relaxations to allow co-epitaxy while preserving conduction;
use ion implantation at the mesa or intra-mesa scale to vary the relaxation (monolithic channel);
use ion implantation at the mesa or intra-mesa scale to vary the relaxation (core-shell channel);
choose the implanted zone to have a uniformity of relaxation and/or an optimization for the circulation of the electrolyte;
reduce the conductivity over the entire surface of the channel by implantation using n++(and optionally carry out a healing annealing);
modulate the implantation conditions to reduce the conductivity of the channel or of the shell as desired.

The invention also relates to a structure comprising a base substrate covered with porosified (Al,In,Ga)N/(Al,In,Ga)N mesas,
the base substrate comprising a support layer, optionally a buffer layer made of (Al,Ga)N, a first layer of undoped GaN and a second layer of doped GaN,
the GaN/(Al,In,Ga)N mesas comprising a third partially porosified layer of (Al,In,Ga)N having a first main face and a second main face, and, preferably, a fourth layer of undoped or weakly doped (Al,In,Ga)N,
a part of the second layer of doped GaN extending into the mesas or a part of the third layer of strongly doped (Al,In,Ga)N extending into the base substrate,
the partially porosified layer of (Al,In,Ga)N comprising one or more non-porosified zones, each non-porosified zone going from the first main face to the second main face of the partially porosified layer of (Al,In,Ga)N to form an electrical conduction channel.

Advantageously, the structure further comprises an additional layer of strongly doped GaN disposed between the first layer of undoped GaN and the second layer of doped GaN.

Such a structure has many advantages:
better tolerance during the etching step, and in particular for the stopping of the post-transfer III-N etching,
a lower relief for creating contact for the cathode (via+metal or transparent conductive oxide (TCO)),
a good compromise between the relaxation rate and the vertical conduction.

The invention also relates to an optoelectronic device successively comprising:
a support substrate, covered by a lower electrode,
a re-epitaxied LED comprising n-InGaN layers and a layer of p-doped InGaN,
a layer of undoped or weakly doped GaN,
a partially porosified layer of (Al,In,Ga)N, having a first main face and a second main face, the partially porosified layer of (Al,In,Ga)N comprising one or more non-porosified zones going from the first main face to the second main face to form an electrical conduction channel,
contact on the non-porosified zone or at least on one of the non-porosified zones of the partially porosified layer of (Al,In,Ga)N.

These non-porosified zones limit the impact on the charge loss (higher Vf) and/or improve optical extraction by reducing or even eliminating the partial blocking. In addition, the non-porous channel(s) promote heat dissipation, which increases reliability.

Thus, it is possible to eliminate the partial blocking due to the metals, by creating the cathode contact vertically in line with the n-(In,Al,Ga)N exclusively with a TCO (i.e. without blocking metal), and by adding metal contact, for example, by a grid placed in the interpixels allowing to homogenize the potential applied onto the cathode.

In addition, the presence of porosified zones allows to:
relax the specifications for the etching of the thick AlGaN/GaN stack to electrically access the n-InGaN while limiting the charge loss,
reduce the relief for creating the cathode contact allowing to use a TCO without blocking,
modulate the shape and the number of non-porosified injection zones to allow maximum relaxation at the center of the mesa and limitthe non-uniformity of relaxation atthe mesa scale,
improve optical extraction (this effect is based on a phenomenon of optical diffusion in the case of large pores).

Other features and advantages of the invention will be clear from the following additional description.

It goes without saying that this additional description is only given as an illustration of the object of the invention and must in no case be interpreted as a limitation of this object.

### BRIEF DESCRIPTION OF THE DRAWINGS

The present invention will be better understood upon reading the description of exemplary embodiments given for purely informational and in no way limiting purposes while referring to the appended drawings in which:

FIGS. 1A to 1C, previously described, schematically show various steps of a method for manufacturing and transferring a micro-LED according to the prior art;

FIGS. 2A to 2C, previously described, show, schematically and in a cross-section, various steps for forming contact starting from the structure of FIG. 1B according to a method of the prior art;

FIGS. 3A to 3C, previously described, show, schematically and in a cross-section, various steps for forming contact starting from the structure of FIG. 1B according to another method of the prior art;

FIGS. 4A to 4D schematically show various steps of a method for manufacturing a micro-LED according to a specific embodiment of the invention;

FIGS. 5A and 5B schematically show various steps of a method for manufacturing a mesa according to a first embodiment of the method according to the invention, the structures are shown in a cross-section according to the dotted line of FIGS. 5C and 5D;

FIGS. 5C and 5D show, in a top view, the mesas of FIGS. 5A and 5B respectively, according to the cutting line shown dotted in FIGS. 5A and 5B;

FIGS. 6A to 6D schematically show various steps of a method for manufacturing a mesa according to a second embodiment of the method according to the invention, the structures are shown in a cross-section according to the dotted lines of FIGS. 6E, 6F, 6G and 6H;

FIGS. 6E to 6H show, in a top view, the mesas of FIGS. 6A, 6B, 6C and 6D respectively, according to the cutting line shown dotted in FIGS. 6A, 6B, 6C and 6D;

FIGS. 7A to 7D schematically show various steps of a method for manufacturing a mesa according to an alternative of the second embodiment of the method according to the invention, the structures are shown in a cross-section according to the dotted lines of FIGS. 7E, 7F, 7G and 7H;

FIGS. 7E to 7H show, in a top view, the mesas of FIGS. 7A, 7B, 7C and 7D respectively, according to the cutting line shown dotted in FIGS. 7A, 7B, 7C and 7D;

FIGS. 8A to 8C schematically show various steps of a method for manufacturing a mesa according to a third embodiment of the method according to the invention, the structures are shown in a cross-section according to the dotted lines of FIGS. 8D, 8E and 8F;

FIGS. 8D to 8F, show, in a top view, the mesas of FIGS. 8A, 8B and 8C respectively, according to the cutting line shown dotted in FIGS. 8A, 8B and 8C;

FIG. 9 is an image obtained with a scanning electron microscope of a mesa obtained according to the first embodiment of the invention.

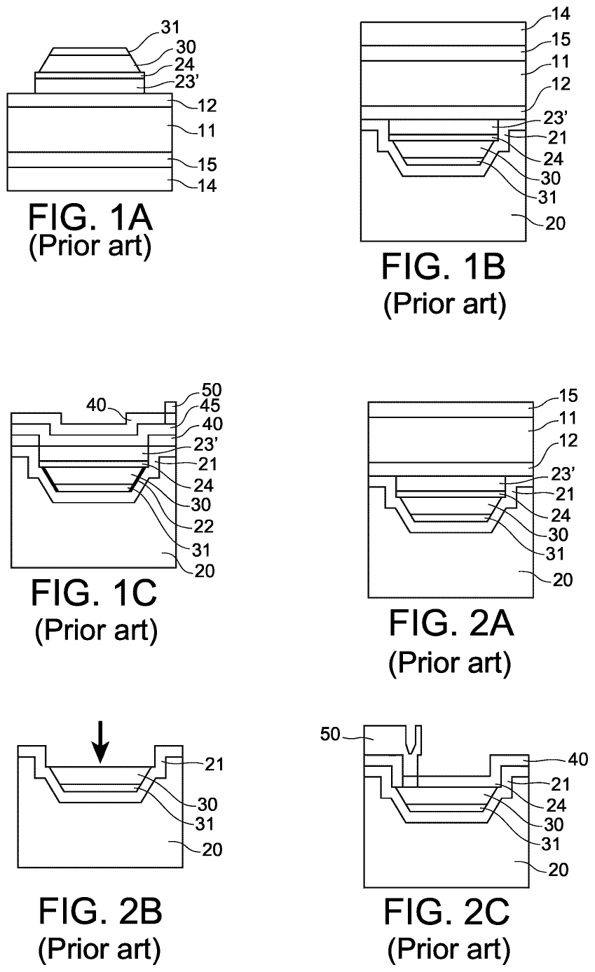

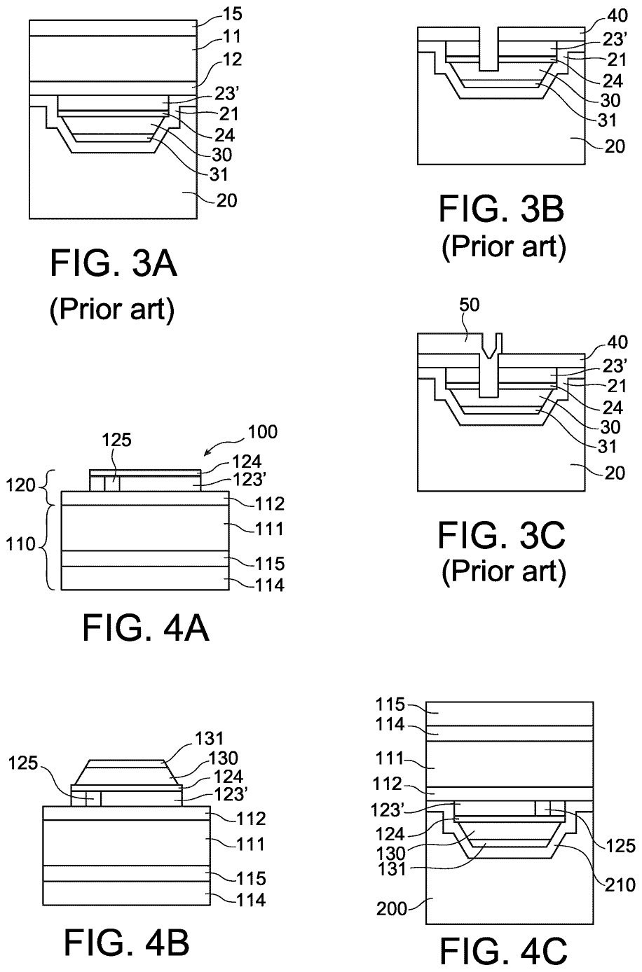

### DETAILED DISCLOSURE OF SPECIFIC EMBODIMENTS

The various parts shown in the drawings are not necessarily shown according to a uniform scale, to make the drawings more readable.

The various possibilities (alternatives and embodiments) must be understood as not being exclusive of each other and can be combined with each other.

Furthermore, in the description below, terms that depend on the orientation, such as “top”, “bottom”, etc. of a structure apply while considering that the structure is oriented in the manner illustrated in the drawings.

Although this is in no way limiting, the invention particularly has uses in the field of color microscreens, and more particularly for manufacturing red green blue pixels. However, it could be used in the field of photovoltaics or water electrolysis (“water splitting”) since, on the one hand, InGaN absorbs in the entire visible spectrum and, on the other hand, its valence and conduction bands are around the range of stability of water, a thermodynamic condition necessary for the water decomposition reaction. The invention can also be of interest for the manufacturing of LEDs or lasers emitting at a large wavelength.

The method is of particular interest for manufacturing structures comprising porosified (Al,In,Ga)N/(Al,In,Ga)N mesas having, in particular, a spacing of less than 30 μm.

(Al,In,Ga)N means AlN, AlGaN, InGaN or GaN. Hereinafter, reference is made more particularly to porous GaN, but with such a method, it is possible to have, for example, porous InGaN or AlGaN.

The dense layer made of InGaN (under compression) or the dense layer made of AlGaN (under tension) will relax via a porous structure regardless of its composition.

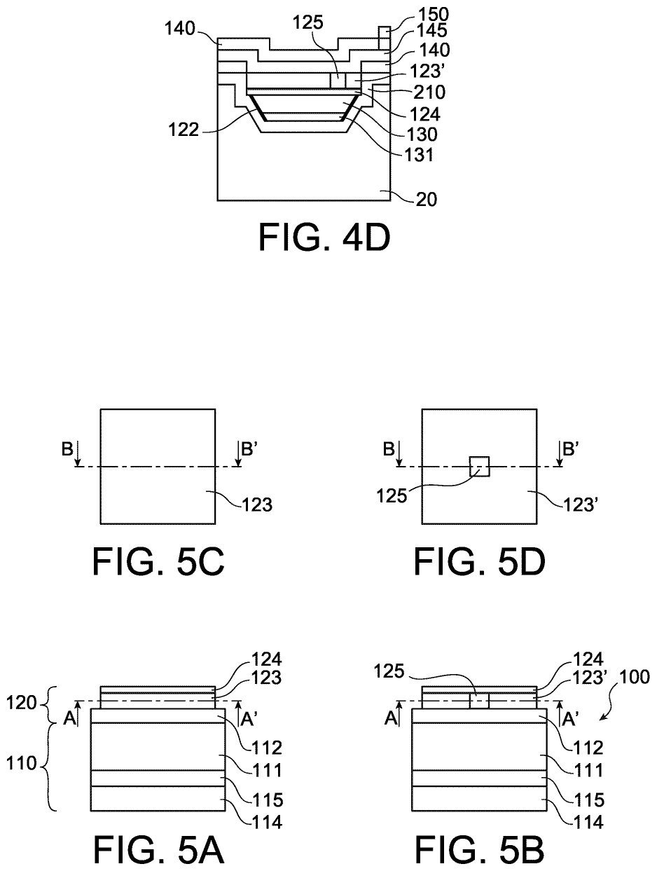

The method for porosifying (Al,In,Ga)N/(Al,In,Ga)N will now be described in more detail in reference to FIGS. 4A to 4D, 5A to 5D, 6A to 6H, 7A to 7H and 8A to 8F.

The method for porosifying mesas 120 of (Al,In,Ga)N/(Al,In,Ga)N comprises the following steps:
a) providing a structure 100 comprising a base substrate 110 covered with (Al,In,Ga)N/(Al,In,Ga)N mesas 120 (FIGS. 5A, 6A-6B, 7A-7B, 8A-8B),
   the base substrate 110 successively comprising:
      a support layer 114,
      optionally a buffer layer 115 made of (Al,Ga)N, in particular in the case of a support layer 114 made of silicon,
      a first layer 111 of undoped GaN,
      advantageously, a highly doped additional layer,
      a second layer 112 of doped GaN,
   the (Al,In,Ga)N/(Al,In,Ga)N mesas 120 comprising a third layer 123 of (Al,In,Ga)N intended to be partially porosified, the third layer 123 of (Al,In,Ga)N being strongly doped or the third layer 123 of (Al,In,Ga)N comprising a first strongly doped part having a first conductivity and a second part formed by one or more zones 125, the second part having a second conductivity at least ten times lower than the first conductivity, wherein a part of the second layer 112 of doped GaN can extend into the mesas 120,
b) electrically connecting the structure 100 and a counter electrode to a voltage or current generator,
c) immersing the structure 100 and the counter electrode in an electrolytic solution,
d) applying a voltage or a current between the structure 100 and the counter electrode so as to partially porosify the third layer 123 of strongly doped (Al,In,Ga)N of the mesas 120 or so as to porosify the first strongly doped part of the third layer 123 of (Al,In,Ga)N of the mesas (the zone(s) 125 of the second part not being porosified), whereby a layer of (Al,In,Ga)N comprising a first porosified part 123′ and a second part formed by one or more non-porosified zones 125 is obtained, each non-porosified zone 125 going from the first main face to the second main face of the partially porosified layer 123′ of (Al,In,Ga)N to form an electrical conduction channel (FIGS. 4A, 5B, 6C, 7C, 8C).

During step a), a fourth layer 124 of undoped or weakly doped (Al,In,Ga)N can cover the third layer 123 of highly doped (Al,In,Ga)N of the (Al,In,Ga)N/(Al,In,Ga)N mesas 120.

Alternatively, after step d), a fourth layer 124 of undoped or weakly doped (Al,In,Ga)N can be deposited on the third porosified layer 123′ of (Al,In,Ga)N. After step d), the doping of the epitaxial regrowth layer is not critical since the porosification was already carried out.

The structure 100 provided in step a) is, for example, obtained by providing then locally etching a stack successively comprising:
a support layer 114,
optionally, a buffer layer 115 made of (Al,Ga)N, in particular in the case of a support layer 114 made of silicon,
a first layer 111 of undoped GaN gallium nitride,
optionally, an additional layer of highly doped GaN (not shown in the drawings),
a second layer 112 of doped GaN (n GaN),
a third layer 123 of strongly doped GaN (n+ GaN or n++ GaN) or a third layer 123 of GaN comprising a first strongly doped part and a second less doped part 125, and
a fourth layer 124 made of unintentionally doped (UID) or weakly doped AlN, InGaN or GaN (noted as (Al,In,Ga)N) if applicable.

Preferably, the stack consists of the layers cited above. In other words, it does not comprise other layers.

According to an advantageous embodiment, a first part of the second layer 112 is part of the base substrate 110 and a second part of the second layer 112 is part of the mesas 120.

The mesas 120 are formed by etching a part of the fourth layer 124, the third layer 123 and a first part of the second doped layer 112 (FIGS. 4A, 5A, 6A and 7A). By stopping etching in the doped layer, the entire height of the third layer 123 of strongly doped GaN is available for the relaxation.

Each mesa 120 successively comprises from the base: the second part of the layer 112 of doped GaN, the third layer 123 of strongly doped GaN and the fourth layer 124 of undoped or weakly doped (Al,In,Ga)N.

The first part of the second layer 112 of doped GaN protects the additional layer during the porosification step. Thus, the additional layer is not in contact with the solution. The first part of the doped GaN layer is a layer common to all the mesas.

The structuring of the stack is, for example, carried out by photolithography.

Thus, a structure 100 comprising a base substrate 110 above which there is a plurality of mesas 120 made of (Al,In,Ga)N/(Al,In,Ga)N is obtained.

The mesas 120, also called elevations, are elements in relief. They are obtained, for example, by etching a continuous layer or several superimposed continuous layers, so as to let only a certain number of “reliefs” of this layer or these layers remain. The etching is preferably carried out with a hard mask, for example SiO₂. After etching of the mesas, this hard mask is removed by a wet chemical method before porosification. It is also possible to remove this hard mask after porosification, by removing it only in the zones used for the polarization for electrochemical polarization. Advantageously, the mask is removed before the porosification step.

Preferably, the sides of the mesas 120 are perpendicular to this stack of layers.

The surface of the mesas can be, for example, circular, hexagonal, square or rectangular.

The largest dimension of the surface of the mesas 120 ranges from 500 nm to 500 μm, preferably from 1 to 10 μm and even more preferably from 3 to 5 μm. For example, the largest dimension of a circular surface is the diameter.

The thickness (or depth) of the mesas corresponds to the dimension of the mesa perpendicular to the underlying stack. The depth of the mesas ranges from 0.3 to 2 μm, preferably from 0.5 to 1 μm.

The spacing between two consecutive 120 mesas ranges from 50 nm to 20 μm.

The mesas 120 can have identical or different dopings. The higher the doping rate, the greater the porosification at a fixed potential. The relaxation of the fourth layer 124 of dense (Al,In,Ga)N depends on the porosification rate of the mesas. Thus, different quantities of indium can be integrated during the re-epitaxy of InGaN on the dense layer 124 (via the reduction of the “compositional pulling effect” (i.e. the pushing of In atoms towards the surface, preventing them from being incorporated into the layer). After epitaxy of the complete LED structure, blue, green and red (RGB) mesas are thus obtained on the same substrate, and in a single growth step, if the difference between the levels of relaxation of the mesas is sufficient.

The support layer 114 is, for example, made of sapphire or made of silicon.

The support layer 114 has a thickness ranging for example from 250 μm to 2 mm. The thickness depends on the nature of the support layer 114 and on its dimensions. For example, for a support layer made of sapphire 2 inches in diameter, the thickness can be 350 μm. For a support layer made of sapphire 6 inches in diameter, the thickness can be 1.3 mm. For a support layer made of silicon 200 mm in diameter, the thickness can be 1 mm.

In the case of a support layer 114 made of silicon, a buffer layer made of (Al,Ga)N is advantageously interposed between the support layer 114 and the layer 111 made of UID GaN.

The first layer 111 is a layer made of undoped GaN. Undoped means unintentionally doped (UID).

It is a UID layer to not be porosified. Unintentionally doped GaN means without voluntary addition of a dopant species during the growth of the GaN, for example with a concentration of less than 101⁷ at/cm³.

The first layer 111 of UID GaN has, for example, a thickness ranging from 500 nm to 5 μm. Advantageously, its thickness is between 1 and 4 μm to absorb the stresses related to the mesh mismatch between the GaN and the substrate.

The second layer 112 is a layer made of doped GaN. Doped GaN means a concentration between 6·10¹⁷ at/cm³ and 5·10¹⁸ at/cm³, preferably between 8.10¹⁷ at/cm³ and 2·10¹⁸ at/cm³.

The second layer 112 made of GaN has a thickness ranging for example from 300 nm to 1 μm, preferably between 400 and 700 nm. It must be sufficiently electrically conductive to be able to create contact on this layer during the electrochemical anodization step. The minimum thickness varies according to the doping rate. The thickness of the layer 112 is chosen so as to protect, if applicable, the strongly doped buried layer during the anodization. This electrically conductive layer can be electrically connected to the voltage or current generator.

The third layer 123 can be a layer of strongly doped (Al,In,Ga)N, for example made of GaN. Strongly doped (Al,In,Ga)N means a concentration greater than 6·10¹⁸ at/cm³, preferably greater than 8·10¹⁸ at/cm³, or even greater than 10¹⁹ at/cm³. The doping rate is therefore higher than that of the second layer 112. The concentration is, for example, between 6·10¹⁸ at/cm³ and 2·10¹⁹ at/cm³, preferably between 7·10¹⁸ at/cm³ and 1·10¹⁹ at/cm³ in the case of n-doping with Si. In the case of Ge doping, for example by metalorganic chemical vapor deposition (MOCVD), higher doping rates, typically up to 1·10²⁰ at/cm³, can be obtained. The third layer 123 has, for example, a doping ten times greater than the second layer 112. It has a thickness of between 200 nm and 2 μm, preferably between 500 nm and 1 μm.

The third layer 123 can be a layer of (Al,In,Ga)N comprising a first strongly doped part in which one or more zones 125 are disposed. The doping rate of the zone(s) 125 is at least ten times lower than the doping rate of the first strongly doped part. The manufacturing of this structured layer so as to have various doping rates will be described in detail below.

The fourth layer 124 is an unintentionally doped or weakly doped (Al,In,Ga)N layer. Weakly doped (Al,In,Ga)N means a doping of between 2·10¹⁷ at/cm³ and 1·10¹⁸ at/cm³. Undoped means a doping rate of less than 10¹⁷ at/cm³, in particular for a layer of GaN. For example, in the case of a layer of InGaN, the doping is less than 5·10¹⁷ at/cm³. The porosification of a given doped layer depends first of all on the potential applied. Furthermore, if the layer to be porosified is strongly doped, the weakly doped layers (typically having a doping at least one decade weaker than the doping of the layer to be porosified) are not porosified.

This can be a layer made of AlN, AlGaN, InGaN or GaN. It has for example a thickness between 10 nm and 200 nm, preferably between 50 and 200 nm. The doping is sufficiently weak so that this layer is not porosified during step d).

This fourth layer 124 is not or is slightly impacted by the porosification and is used as a seed for regrowth. This fourth layer 124 is continuous to ensure the quality of the layer re-epitaxied, of a layer of (In,Ga)N for example, on the structure.

The additional layer has a thickness of, for example, between 500 nm and 5 μm, preferably between 1 μm and 3 μm. Preferably, it has a doping concentration greater than or equal to 5·10¹⁸ at·cm³, preferably greater than 6·10¹⁸ at·cm³, even more preferably greater than 8·10¹⁸ at·cm³, or even greater than 10¹⁹ at·cm³, for example 1.5·10¹⁹ at·cm³. It has a doping concentration, for example, between 6·10¹⁸ at/cm³ and 2·10¹⁹ at/cm³, preferably between 7·10¹⁸ at/cm³ and 1·10¹⁹ at/cm³. The additional layer made of strongly doped GaN can have a doping identical to or different from that of the third layer made of strongly doped GaN. The additional layer of strongly doped GaN can have a thickness identical to or different from that of the third layer 123 made of strongly doped (Al,In,Ga)N.

The voltage applied during porosification is chosen according to the dopings of the various aforementioned layers, and in particular of the second layer 112, of the third layer 123 and of the additional layer, as well as the target doping rate.

The respective doping rates are chosen so that at a given potential, there is selectivity between the strongly doped zone and the weakly doped zone, that is to say so that the second layer 112 is not porosified during step d) and so that the third layer 123 is porosified during step d).

Below, n-type doping is described, but this could be p-type doping.

For illustrative and non-limiting purposes, according to an alternative embodiment, the structure 100 can comprise:
a base substrate 110 successively comprising: a support layer 114 made of sapphire or made of silicon, optionally a buffer layer 115 made of (Al,Ga)N, a first layer 111 of undoped GaN having a thickness of between 1 and 4 μm, a first part of the second layer 112 of doped GaN of 500 nm (1·10¹⁸ at/cm³),
GaN/(Al,In,Ga)N mesas 120 successively comprising: a second part of the second layer 112 of doped GaN of 100 nm (1·10¹⁸ at/cm³), a third layer 123 of strongly doped GaN of 800 nm (1·10¹⁹ at/cm³), and a layer of UID (Al,In,Ga)N of 100 nm.

According to another alternative embodiment, the structure 100 can comprise:
a base substrate 110 successively comprising: a support layer 114 made of sapphire or made of silicon, optionally a buffer layer 115 made of (Al,Ga)N, a first layer 111 of undoped GaN having a thickness of between 1 and 4 μm, an additional layer of strongly doped GaN of 2 μm (1·10¹⁹ at/cm³), a first part of the second layer 112 of doped GaN of 500 nm (1·10¹⁸ at/cm³),
GaN/(Al,In,Ga)N mesas 120 successively comprising: a second part of the second layer 112 of doped GaN of 100 nm (1·10¹⁸ at/cm³), a third layer 123 of strongly doped GaN of 800 nm (1·10¹⁹ at/cm³), and a fourth layer 124 of UID (Al,In,Ga)N of 100 nm.

During step b), the structure 100 and a counter electrode (CE) are electrically connected to a voltage or current generator. The device acts as a working electrode (WE). Below, it will be called voltage generator, but this could be a current generator allowing to apply a current between the device and the counter electrode.

The contact is made on the structure 100.

In particular, the contact can be made on the base substrate 110. Contact can also be made on the second layer 112 of doped GaN. The contact can be made on the bottom of the mesas, at the second layer 112, which allows to use the etching step to also carry out the contact.

It is also possible to create contact on one of the other layers: on the fourth layer 124 of undoped or weakly doped (Al,In,Ga)N, on the third layer 123 of strongly doped (Al,In,Ga)N or on the additional layer of strongly doped GaN. In the case of contact on a strongly doped layer, its opening is, advantageously, limited to a zone preserved from the electrolyte.

The contact zone can also be overlaid with a metal layer in order to improve the contact for the electrochemical polarization. This contact can be removed after the porosification before the epitaxial regrowth.

The counter electrode 500 is made of an electrically conductive material, such as for example a metal having a large surface area and inert to the chemistry of the electrolyte such as a platinum grid.

During step c), the electrodes are immersed in an electrolyte, also called electrolytic bath or electrolytic solution. The electrolyte can be acidic or basic. The electrolyte is, for example, oxalic acid. It can also be KOH, HF, HNO₃, NaNO₃ or H₂SO₄.

During step d), a voltage is applied between the structure 100 and the counter electrode 500. The voltage can range from 1 to 30V, for example. Preferably, it is from 5 to 15V, and even more preferably from 6 to 12V, for example from 8 to 10V. The voltage is chosen according to the doping rates of the various layers, in order to obtain the desired selectivity. It is applied, for example, for a duration ranging from several seconds to several hours. The porosification is complete when there is no longer any current with a potential imposed. At this point, the entire doped structure is porosified and the electrochemical reaction stops.

The electrochemical anodization step can be carried out under ultraviolet (UV) light.

During step d), the third layer 123 of (Al,In,Ga)N is partially porosified. Otherwise, one or more zones 125 of the layer 123 of strongly doped GaN are not porosified during step d).

Each non-porosified zone goes from the first main face to the second main face to form an electrical conduction channel through the layer of GaN. The electrical conduction channel can have the shape of a channel or a tube for example. Thus, it is possible to create contact on the GaN layer at this electrical conduction channel.

In addition, by choosing the position of the non-porosified zones, it is possible to affect the relaxation.

According to a first advantageous embodiment, shown in FIGS. 5A to 5C, step d) is a step of incomplete porosification: step d) is carried out while stopping the voltage or the current before the complete porosification of the layer of (Al,In,Ga)N, whereby the non-porosified zone 125 corresponds to the central part of the partially porosified layer 123′ of (Al,In,Ga)N.

The porosification begins on the sides of the mesas at the layer 123 of GaN in contact with the electrolyte and extends towards the center of the layer of GaN. As the porosification occurs, the electrolyte progresses towards the core. This lateral porosification from the mesa edge is controlled by the duration of the electrochemical porosification. The core of the mesas remains intact (i.e. it is not porosified). The cores of the mesas form conduction channels going from the first main face to the second main face of the partially porosified layer 123′ of (Al,In,Ga)N. The core of the layer 123′ thus created, here made of n++ GaN, has an intact conductivity.

This first embodiment is particularly suitable for mesas of large dimensions (for example greater than or equal to 5 μm).

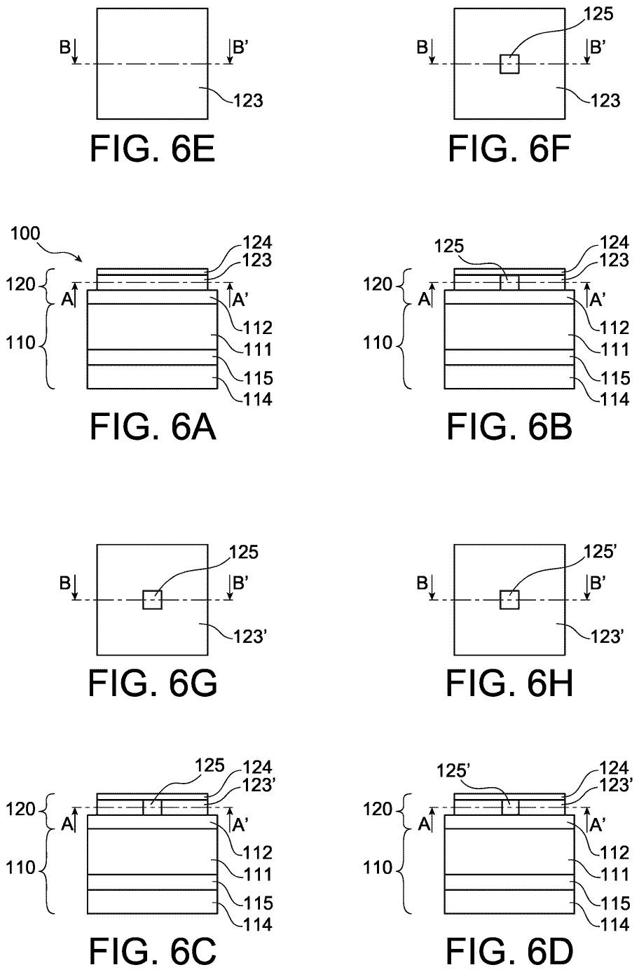

According to a second advantageous embodiment, shown in FIGS. 6A to 6H, one or more zones 125 having a second electrical conductivity are formed in the layer 123 of strongly doped (Al,In,Ga)N before the porosification step. The second conductivity is at least ten times lower than the first conductivity, whereby during step d), the zone(s) 125 of lower conductivity are not porosified.

These zones are, for example, obtained by localized ion implantation of the n++ layer 123 of the mesas in order to form non-porous pillars. The implantation leads to a degradation of the conductivity of the implanted part (this part is strongly doped before implantation and doped or even weakly doped after implantation). Preferably, the implantation allows to modulate the doping by approximately a decade and in particular to decrease it by at least one decade (for example for GaN:Si, the doping rate can go from 10¹⁹ at/cm³ to 10¹⁸ at/cm³ or less). During step d), this zone 125 is not or is slightly porosified since it is less conductive. The zone can be at the center of the mesa as shown in FIGS. 6B, 6C, 6F and 6G.

Advantageously, for this second embodiment, it is possible, after the porosification step d), to carry out a heat treatment. This is an annealing for healing the implantation defects. This annealing allows to at least partially recover the conductivity of the non-porosified implanted zone and thus to form a conduction channel 125′ of higher conductivity (FIGS. 6D and 6H).

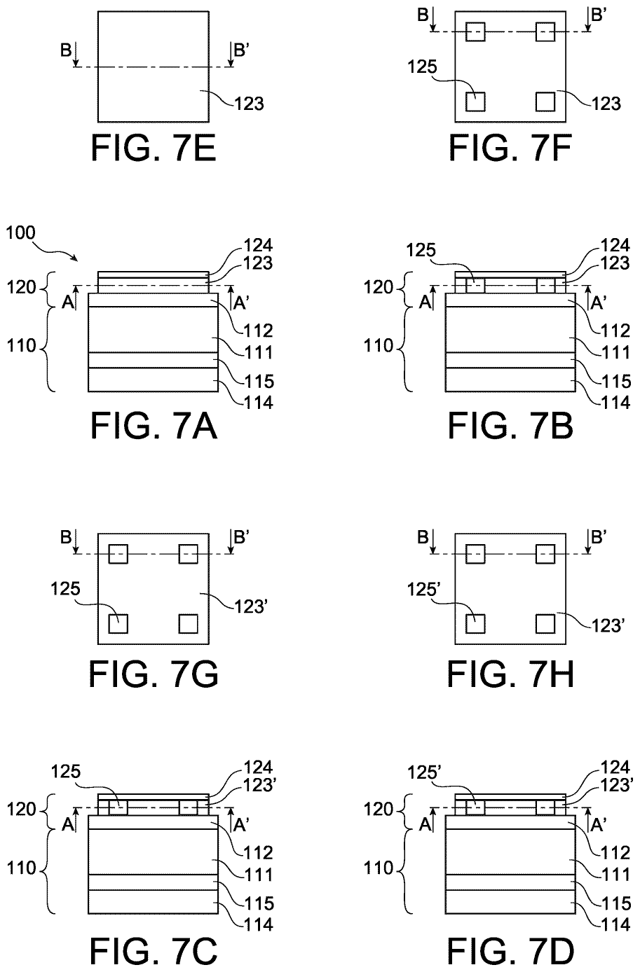

According to an alternative embodiment, shown in FIGS. 7A to 7H, it is possible to implant several parts of the layer 123 of (Al,In,Ga)N to modulate the position of the porosified zones and of the non-porosified zones 125. This alternative is of particular interest since it allows to preserve the relaxation of the core and/or minimize the degradation of the surface of the re-epi seed.

Like above, it is possible to carry out an annealing step to increase the conductivity of the pillars and have a conductivity zone 125′ with improved conductivity.

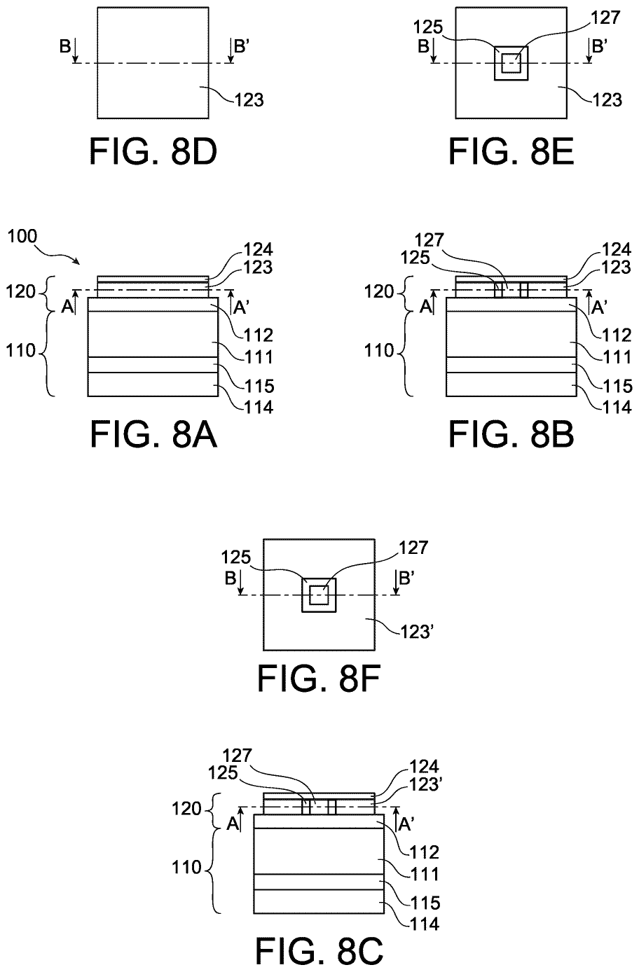

According to a third advantageous embodiment, shown in FIGS. 8A to 8F, the layer 123 of strongly doped (Al,In,Ga)N is locally modified so as to form, in the third layer 123 of strongly doped (Al,In,Ga)N, one or more zones 125 having a conductivity at least ten times lower than the first conductivity. These zones 125 go from the first face to the second face of the layer 123. These zones preferably have a tube shape and protect a core 127 located inside the tube (this is the central part of the tube). The central part of the tube has, for example, the same conductivity as the first part of the layer 123 of (Al,In,Ga)N (that is to say the inside of the tubes is strongly doped). The zones 125 form a protective wall with respect to the anodization for the zones 127 to be protected. Thus, during step d), the core 127 of the tubes is not porosified and forms preferred conduction channels.

This third embodiment consists, for example, in carrying out a localized ion implantation of the third n++ layer 123 of the mesas, preferably in the form of rings, to electrically preserve n++ pillars, in the core of the rings, without degrading their conductivity. Thus, after step d), a non-porous implanted ring surrounding an intact non-implanted n++ core is obtained, the ring itself being in contact with the rest of the non-implanted and porosified layer. The non-porous pillars ensure the electrical conduction.

The parameters of the implantation are chosen so as to degrade (i.e. to decrease) the conductivity in the implanted zones by at least a factor of 10. A lower value does not prevent good conductivity by the channels that remain intact.

In FIGS. 8A to 8F, a single ring 125/core 127 unit is shown. Several units can advantageously be defined to form several conduction channels through the third layer 123. The positioning of the core/ring units is, advantageously, chosen so as to obtain good relaxation.

According to the second embodiment and the third embodiment, preferably, the non-porous conduction pillars have a diameter of at least 250 nm.

The channel is preferably solid (i.e. made of the same material).

The channel goes from the first main face of the layer of GaN to the second main face of the layer 123 of GaN. The height of the channel corresponds to the thickness of the third layer 123 of GaN.

The surface of the channel can have a round, hexagonal, square, etc. shape. The largest dimension of the surface of the channel is, preferably, at least 0.25 μm, in particular with respect to the ease of implementation (critical dimensions in photolithography).

The conduction channel(s) can be positioned at the center or at the periphery of the mesa.

The surface area of the non-porous channel or the total surface area of the non-porous channels as well as the position of the non-porous channel(s) affect the relaxation.

In these various embodiments, it has been described that the various parts of the layer of (Al,In,Ga)N are obtained by providing a layer 123 of strongly doped (Al,In,Ga)N having a first electrical conductivity, then by locally decreasing the electrical conductivity of the layer of (Al,In,Ga)N, to form a layer comprising a first strongly doped part and a second part formed by one or more zones 125 of lower conductivity.

Alternatively, it is also possible to form the various parts of the layer of (Al,In,Ga)N by providing a layer of (Al,In,Ga)N having a low electrical conductivity (for example by starting from an unintentionally doped or weakly doped layer) then by locally increasing the electrical conductivity of the layer of (Al,In,Ga)N by at least a factor of 10, to form a strongly doped part. The increase in conductivity is, for example, achieved by implantation of dopants (donors for n).

For each of the alternatives, it is possible to obtain a first strongly doped part in which one or more less conductive pads 125 are dispersed or in which one or more structures comprising a less conductive ring 125 surrounding a conductive core 127 are dispersed.

The following table lists several pieces of data on the mesas. The resistivity values are taken from the literature.

| Non-porous channel | | Non-porous | | | Upper layer n- | Upper layer UID |
|---|---|---|---|---|---|---|
| 125: 10¹⁹at/cm³ | | mesa: 10¹⁹at/cm³ | All-porous mesa | | GaN mesa 124 | GaN mesa 124 |
| 1 μm² | 0.1 μm² | 10 μm² | Poro 10% | Poro 70% | 1E18 cm⁻³ | 1E17 cm⁻³ |
| 1 | 1 | 1 | 1 | 1 | 0.1 | 0.1 |
| 1 | 0.1 | 10 | 10 | 10 | 10 | 10 |
| 3.0E−03 | 3.0E−03 | 3.0E−03 | 5.0E−02 | 1.0E+00 | 1.6E−02 | 1.3E−01 |
| 3.0E+01 | 3.0E+02 | 3.0E+00 | 5.0E+01 | 1.0E+03 | 1.6E+00 | 1.3E+01 |
| 100 | 100 | 100 | 100 | 100 | 100 | 100 |
| 6 | 6 | 6 | 6 | 6 | 6 | 6 |
| 6.0E−06 | 6.0E−06 | 6.0E−06 | 6.0E−06 | 6.0E−06 | 6.0E−06 | 6.0E−06 |
| 0.18 | 1.8 | 0.018 | 0.3 | 6 | 0.0096 | 0.078 |

According to the values in the table, it appears that a non-porous channel (or several non-porous channels, with an equivalent surface area of 1 μm²) can greatly reduce the vertical resistance of a greatly porosified porous mesa of 10 μm² (potential drop in the mesa reduced from 6V to 0.18V, or more than a factor of 30). In this case, it is possible to preserve the porous GaN in the device after transfer. The potential drop induced by the upper layer 124 of the mesa remains low relative to the potential drop of the mesa, which allows to keep the mesa porous without significant degradation of the electrooptical characteristics.

The porosity rate of the porosified part of the third layer 123 of strongly doped (Al,In,Ga)N is, advantageously, at least 10%. It preferably ranges from 25% to 70%, preferably from 25% to 50%, for example 45% 50%.

The largest dimension (the height) of the pores can vary from several nanometers to several micrometers. The smallest dimension (the diameter) can vary from several nanometers to about a hundred nanometers, in particular from 30 to 70 nm.

The porosification obtained (porosity rate and size of the pores) depends on the doping of the layer and the parameters of the method (voltage applied, duration, nature and concentration of the electrolyte, chemical post-treatment or annealing). The variation in the porosification allows to control the rate of incorporation/segregation. The porosification, and in particular, the size of the pores, can vary later, during the epitaxial regrowth, according to the temperature applied.

After step d), the method advantageously comprises the following steps:
e) on the structure obtained in step i), carrying out an epitaxial regrowth to form re-epitaxied LEDs comprising layers 130 of n-InGaN and a layer 131 of p-doped InGaN (FIG. 4B), then forming a contact electrode 210, wherein a dielectric 122 can be deposited to protect the sides of the LED,
f) transferring the structure obtained in step f) onto a substrate 200, for example by metal-metal bonding (FIG. 4C),
g) removing the support layer 114, if applicable the buffer layer 115 made of (Al,Ga)N, the first layer 111 of undoped GaN and the entirety or a part of the second layer 112 of doped GaN (preferably, the part that is located outside the mesas),
h) creating contact 150 on the non-porosified zone 125 or at least on one of the non-porosified zones 125 of the partially porosified layer 123′ of (Al,In,Ga)N (FIG. 4D).

Advantageously, an electrically insulating layer 140 protects the porosified layer and/or prevents short circuits.

During step e), the reflector contact electrode 210 on p-InGaN is positioned on the structure. The contact electrode 210 is an “upper” electrode before transfer and this same electrode is “lower” after transfer.

A passivation layer 122 can be positioned between the contact electrode 210 (anode) and the layer 131 of p-doped InGaN. The passivation layer 122 locally covers the layer 131 of p-doped InGaN, in particular on the inclined sides of the layer 131 of p-doped InGaN.

During step e), an epitaxy is carried out on the mesas 120, whereby an at least partially relaxed, and preferably totally relaxed, epitaxied layer is obtained.

For example, an all-InGaN LED structure can comprise
a layer of n-doped InGaN of 350 nm, formed by 15×In_{0.03}Ga_{0.97}N/GaN (thicknesses 20 nm/1.8 nm),
multiple quantum wells (MQWs), formed by 5×In_{0.40}Ga_{0.60}N/In_{0.03}Ga_{0.097}N (thicknesses 2, 3 nm/5, 7, 11 nm),
a layer of UID In_{0.03}Ga_{0.97}N (10 nm),
an Al_{0.1}Ga_{0.9}N:Mg layer (20 nm),
a layer of Mg-doped In_{0.03}Ga_{0.97}N (125 nm),
a layer of p+++ doped In_{0.03}Ga_{0.97}N (25 nm).

The percentage of relaxation corresponds to: Δa/a=(a_{c2}−a_{c1})/a_{c1}, with a_{c1} the mesh parameter of the starting layer on which the epitaxial regrowth is carried out (that is to say the mesh parameter of the layer 124), and a_{c2} the mesh parameter of the relaxed layer.

The layer is relaxed to 100% if ac₂ corresponds to the mesh parameter of the bulk material, having the same composition as the re-epitaxied layer.

When ac1=ac₂, the layer is called stressed.

Partially relaxed means, for example, a percentage of relaxation greater than 50%. The percentage of relaxation depends on the final mesa (for example, blue, green or red mesa). The doping rate of the mesas can be modulated so as to have different porosity rates and therefore relaxation rates according to the mesas during the epitaxial regrowth of InGaN emitters. This facilitates the obtaining of various emission colors according to the mesas, for example to obtain red, green and blue emitters by growth on the same substrate. It is also possible to obtain various emission colors by changing the porosified/non-porosified surface ratio or by combining the two.

The epitaxial regrowth is preferably used to form re-epitaxied LEDs.

The epitaxial regrowth is carried out on the fourth layer 124 of UID or weakly doped (Al,In,Ga)N of the mesas 120. Since this layer is not porosified during the electrochemical anodization step, it remains continuous and dense. The epitaxial regrowth is thus facilitated and the epitaxied layer has better strength. The creation of defects related to the coalescence of the pores is avoided.

The layer epitaxied during this step e) is advantageously made of gallium nitride or made of indium gallium nitride.

The rate of incorporation of In varies according to the relaxation capacity (mesh parameter a in the plane). By acting on the porosification rate and the amount of porosified surface, the mesas can have different relaxation rates. For example, it is possible to act on the n++ GaN differential de-doping by (He) implantation.

The method is thus easier to implement since a single epitaxy is sufficient to form the red, green and blue μLEDs. There is no need to implement successive epitaxies for each pLED.

Step f) is, for example, obtained with metal-metal bonding. This could also be a hybrid (metal-oxide) bonding. This step allows, in particular, to carry out the interconnection with a control circuit to dynamically modulate the emission of the micro-LEDs.

During step h), the contact 150 can be carried out via the presence of a layer 145 of transparent conductive oxide (TCO). The layer of TCO 145 is for example made of indium tin oxide (ITO). It is possible to cover the TCO layer 145 with an additional passivation layer 140 to protect it (FIG. 4D).

### Illustrative and Non-Limiting Example:

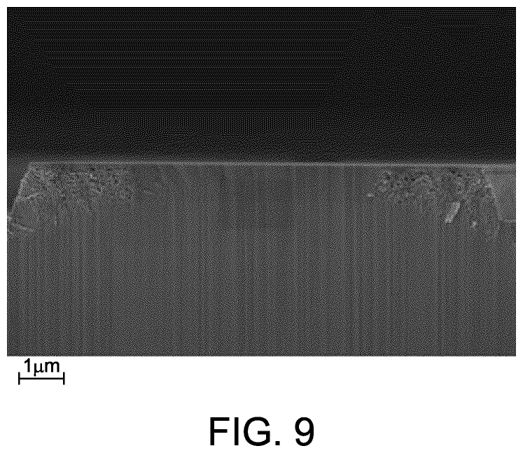

A mesa comprising a layer of n++ doped GaN was partially porosified. The porosification is stopped by stopping it before its total completion (FIG. 9).

The central channel of n++ GaN in the mesas has an intact conductivity.

1. A method for porosifying (Al,In,Ga)N/(Al,In,Ga)N mesas comprising the following steps:
a) providing a structure comprising a base substrate covered with (Al,In,Ga)N/(Al,In,Ga)N mesas,
the base substrate comprising a support layer made of (Al,Ga)N, a first layer of undoped GaN, a second layer of doped GaN,
the (Al,In,Ga)N/(Al,In,Ga)N mesas comprising a third layer of (Al,In,Ga)N having a first main face and a second main face,
the third layer of (Al,In,Ga)N being strongly doped or the third layer of (Al,In,Ga)N comprising a first strongly doped part having a first electrical conductivity, and a second part formed by one or more zones, the second part having a second electrical conductivity at least ten times lower than the first electrical conductivity,
wherein a part of the second layer of doped GaN can extend into the mesas,
b) electrically connecting the structure and a counter electrode to a voltage or current generator,
c) immersing the structure and the counter electrode in an electrolytic solution, and
d) applying a voltage or a current between the structure and the counter electrode so as to partially porosify the third layer of strongly doped (Al,In,Ga)N of the mesas or so as to porosify the first strongly doped part of the third layer of (Al,In,Ga)N of the mesas,
whereby a layer of (Al,In,Ga)N comprising a first porosified part and a second part formed by one or more non-porosified zones is obtained, each non-porosified zone going from the first main face to the second main face of the partially porosified layer of (Al,In,Ga)N to form an electrical conduction channel.

2. The method according to claim 1, wherein the structure further comprises an additional layer of strongly doped GaN disposed between the first layer of undoped GaN and the second layer of doped GaN.

3. The method according to claim 1, wherein,
during step a), a fourth layer of undoped or weakly doped N covers the third layer of strongly doped (Al,In,Ga)N, or
after step d), a fifth layer of undoped or weakly doped (Al,In,Ga)N is deposited on the partially porosified layer of (Al,In,Ga)N.

4. The method according to claim 3, wherein the fourth or fifth layer of undoped or weakly doped (Al,In,Ga)N is a layer of GaN.

5. The method according to claim 1, wherein d) comprises stopping the voltage or the current before complete porosification of the third layer of (Al,In,Ga)N, whereby the non-porosified zone corresponds to a central part of the partially porosified layer of (Al,In,Ga)N.

6. The method according to claim 1, wherein the zone(s) of the third layer of (Al,In,Ga)N form rings, each ring defining a core having an electrical conductivity at least ten times greater than the second electrical conductivity, whereby during d), the cores are not porosified and form electrical conduction channels.

7. The method according to claim 1, wherein, after d), the method comprises carrying out a heat treatment, whereby the second electrical conductivity is increased and zones having a third electrical conductivity greater than the second electrical conductivity are obtained.

8. The method according to claim 1, wherein the third layer of (Al,In,Ga)N of a) is obtained according to:
providing a layer of strongly doped (Al,In,Ga)N having a first electrical conductivity, and
locally reducing the electrical conductivity of the layer of strongly doped (Al,In,Ga)N, whereby a layer of (Al,In,Ga)N is formed comprising a first strongly doped part having a first electrical conductivity and a second part formed by one or more zones having a second electrical conductivity at least ten times lower than the first electrical conductivity.

9. The method according to claim 1, wherein the third layer of (Al,In,Ga)N of a) is obtained according to steps:
providing a layer of (Al,In,Ga)N having a second electrical conductivity, and
locally increasing the electrical conductivity of the layer of (Al,In,Ga)N having the second electrical conductivity, whereby a layer of (Al,In,Ga)N is formed comprising a first strongly doped part having a first electrical conductivity and a second part formed by one or more zones having a second electrical conductivity at least ten times lower than the first electrical conductivity.

10. The method according to claim 1, wherein three groups of mesas are formed, each group of mesas being configured to form a red, green or blue micro-LED, each group of mesas having a different porosification rate or percentage of porosified surface.

11. A method for manufacturing a micro-LED, comprising:
i) implementing the method for porosifying mesas according to claim 1, and
ii) implementing the following operations e) to g):
e) on the structure obtained in i), carrying out an epitaxial regrowth to form re-epitaxied LEDs comprising layers of n-InGaN and a layer of p-doped InGaN, then forming a contact electrode, wherein a passivation layer can be positioned between the contact electrode and the layer of p-doped InGaN, the passivation layer locally covering the layer of p-doped InGaN,
f) transferring the structure obtained in e) onto a substrate,
g) removing the support layer made of (Al,Ga)N, the first layer of undoped GaN and the second layer of doped GaN, and
h) creating contact on the non-porosified zone or at least on one of the non-porosified zones of the partially porosified layer of (Al,In,Ga)N.

12. A structure comprising a base substrate covered with porosified (Al,In,Ga)N/(Al,In,Ga)N mesas,
the base substrate comprising a support layer made of (Al,Ga)N, a first layer of undoped GaN, and a second layer of doped GaN,
the (Al,In,Ga)N/(Al,In,Ga)N mesas comprising a third partially porosified layer of (Al,In,Ga)N having a first main face and a second main face,
the partially porosified layer of (Al,In,Ga)N comprising one or more non-porosified zones, each non-porosified zone going from the first main face to the second main face of the partially porosified layer of (Al,In,Ga)N to form an electrical conduction channel.

13. The structure according to claim 12, wherein the structure further comprises an additional layer of strongly doped GaN disposed between the first layer of undoped GaN and the second layer of doped GaN.

14. An optoelectronic device,
successively comprising:
a support substrate,
a lower electrode,
a re-epitaxied LED comprising layers of n-InGaN and a layer of p-doped InGaN,
a layer of undoped or weakly doped (Al,In,Ga)N,
a partially porosified layer of (Al,In,Ga)N, having a first main face and a second main face,
the partially porosified layer of (Al,In,Ga)N comprising one or more non-porosified zones going from the first main face to the second main face to form an electrical conduction channel, and
a contact on the non-porosified zone or at least on one of the non-porosified zones of the partially porosified layer of (Al,In,Ga)N.
